(19) United States
(12) Patent Application Publication
(10) Pub. No.: US 2022/0221510 A1
(43) Pub. Date: Jul. 14, 2022

(54) LASER-INDUCED THERMAL STRESSING OF INTEGRATED CIRCUITS

(71) Applicant: Intel Corporation, Santa Clara, CA (US)

(72) Inventors: Ricardo Ascazubi, Hillsboro, OR (US); Georgia Modoran, Portland, OR (US)

(73) Assignee: Intel Corporation, Santa Clara, CA (US)

(21) Appl. No.: 17/711,878

(22) Filed: Apr. 1, 2022

(51) Int. Cl. G01R 31/28; H05B 3/00; B23K 26/082; B23K 26/035

(52) U.S. Cl. CPC G01R 31/2875; H05B 3/0038; G01R 31/2863; B23K 26/035; G01R 31/2868; B23K 26/082

(57) ABSTRACT

Laser-based integrated circuit (IC) device testing apparatus capable of inducing localized regions of high temperature within an IC device under test (DUT). A laser source of sufficiently high output power (e.g., 1 W) within an output band that has an energy less than that of a bandgap of one or more semiconductor materials within the DUT may heat a target portion of the DUT proximal to active devices. High levels of thermal stress are possible with the ability to induce temperatures of 300° C., or more. High spatial resolution of thermal stress with the DUT is possible with laser beam spot diameters of less than 4 μm. Accelerated aging tests and thermal sensitivity characterizations of a DUT may be implemented with laser-based heating to expand the range of possible testing conditions and/or generate more precise test data at a more rapid pace.

### BACKGROUND

High-temperature operating life (HTOL) is an accelerated aging test applied to integrated circuits (ICs), typically in their packaged form, to determine their reliability. The HTOL test stresses an IC by operating it at elevated temperature(s) and elevated supply rail voltage(s) for a predetermined period of time.

HTOL may utilize the conventional test system 100 illustrated in FIG. 1. Test system 100 includes an oven 115, for example including a heater 120 and a fan 125 to reach a predetermined stress temperature Tₛ. An IC device (e.g., packaged die) 101 under test is placed within oven 115, for example operatively coupled a reference host board 110 that is powered by a power supply 112. When powered, host board 110 provides signals to operate IC die 101.

IC die 101 is typically monitored under HTOL stress and periodically tested at predetermined intervals during a stress test. Accordingly, the HTOL stress test is sometimes referred to as a “lifetime test,” “device life test,” or “extended burn in test” and may be used to identify potential failure modes within IC die 101, for example during designed validation, and assess an IC lifetime against full-lifetime requirements for various standard use conditions (e.g., commercial, automotive, telecom, etc.).

In the practice of HTOL, reliability engineers are tasked with verifying an adequate stress duration. For example, for an activation energy of 0.7 eV, a stress temperature Tₛ of 125° C. and a use temperature of 55° C., an expected operational life of five years might be represented by a 557-hour HTOL experiment.

Implementing HTOL with test system 100 poses several problems. First, all the possible failure modes of IC die 101 will manifest with competing failure rates. The reliability engineer must accordingly disposition all the different sources of failures observed across IC die 101. However, finding each root cause can be exceedingly difficult and time consuming. Second, the HTOL platforms used to stress IC die 101 (e.g., host board 110) often have limited power delivery capacity and elevating power during accelerated lifetime stress testing can compromise the power delivery systems. For example, voltage regulators, thermal diode sensing schemes, and maximum current envelopes of components external to the IC (e.g., in host board 110) may limit the maximum practical temperature stress condition.

These same difficulties impact more than IC operating life determinations. Regardless of the lifetime of a particular IC die, designed IC die temperature limits can have a profound effect on IC performance Hence, simulation of thermal effects within an IC die are very important to an IC design development process seeking optimal IC performance. For example, IC clock throttling algorithms may be predicated on thermal effects within the IC die, and if incorrect, IC performance may suffer from overly aggressive clock throttling. Experimental validation of thermal simulation employed in IC design is therefore important, but not readily available because of one or more of the problems noted above.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is schematic of a conventional IC device testing system suitable for thermally stressing an IC device under test (DUT);

FIG. 2A is a schematic of a laser-based testing system suitable for inducing hot spots localized to only a portion of a DUT, in accordance with some embodiments;

FIG. 2B is an isometric illustration of an optical encoder of a galvanometer suitable for the laser-based testing system illustrated in FIG. 2A, in accordance with some embodiments;

FIGS. 3A and 3B are schematics of a laser-based testing system suitable for inducing hot spots localized to only a portion of a DUT, in accordance with some alternative embodiments;

FIG. 4 is a graph illustrating a correlation between laser output power and temperature within a target portion of a DUT, in accordance with some embodiments;

FIG. 5 is a graph illustrating a temperature profile spanning a target spatial portion of a DUT heated in accordance with some embodiments; and

FIG. 6 is a flow diagram illustrating laser-based methods of inducing localized hot spots at the circuit level within an IC device under test (DUT) that is otherwise under nominal conditions, in accordance with some embodiments;

FIG. 7 is a graph illustrating temperature sensitivity of a PLL circuit as temperature is increased, in accordance with some embodiments;

FIG. 8 is a block diagram of a data processing system, in accordance with some embodiments; and

FIG. 9 is a diagram of an exemplary computer system including logic to perform laser-based HTOL testing, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any possible combinations of one or more of the associated listed items.

The terms “coupled” and “connected,” along with their derivatives, may be used herein to describe functional or structural relationships between components. These terms are not intended as synonyms for each other. Rather, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The term “signal” may refer to at least one current signal, voltage signal, magnetic signal, or data/clock signal.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

As used throughout this description, and in the claims, a list of items joined by the term “at least one of” or “one or more of” can mean any combination of the listed terms.

Unless otherwise specified in the explicit context of their use, the terms “substantially equal,” “about equal” or “approximately equal” mean that there is no more than incidental variation between two things so described. In the art, such variation is typically no more than +/−10% of a predetermined target value.

Transistor technologies continue to scale IC devices to have higher power densities. This trend is expected to cause extreme local temperatures. Therefore, concern for fin self-heat (FISH), thermal runaway, electromigration and negative bias temperature instability (NBTI) increases with each generation of IC design and fabrication technology.

In accordance with embodiments herein, localized hot spots in an IC die running under nominal or accelerated use conditions may by generated through targeted laser beam irradiation. As described further below, this technique enables thermal effects characterizations including the validation of temperature design limits as well as temperature aging/sensitivity analysis of select functional circuit blocks of a DUT with both high spatial resolution and speed. For example, the intensity of heating possible by laser irradiation enables days of laser stress to be the equivalent of several years of actual use. All the while, circuitry of the DUT not irradiated by the laser beam may advantageously remain unperturbed, thereby reducing the number of competitive failure modes. As used herein a functional circuit block is a block of circuitry within a larger device architecture that perform a particular function. Examples of a functional circuit block include, but are not limited to, a ring oscillator, a phase locked loop, or a memory array (e.g., NAND, SRAM, DRAM, etc.). Although a functional circuit block may have any number of transistors, in some embodiments a functional circuit block includes at least many hundreds of transistors.

Embodiments herein may be referred to as Laser-Assisted Thermal Stressing (LATS), with one goal being to accelerate the aging of circuitry within targeted regions of a DUT that is heated through laser irradiation. Unlike Laser-Assisted Device Alteration (LADA), in which laser irradiation induces operationally sensitive transistors to advance or retard their switching characteristics in order to alter the pass/fail outcome of some pre-determined marginal test stimulus exercising the IC device, high temperatures induced by laser-assisted thermal stressing accelerates reliability mechanisms within a targeted portion of an IC device. In exemplary embodiments, age-related damage is induced to permanently alter the targeted circuitry blocks through any mechanisms known to occur during normal operation, albeit at a much lower rate in the absence of such laser-based thermal stress.

In contrast to LADA systems, which typical employ lasers with average power of only a few tens of milliwatts, the laser source in LATS embodiments herein have an average power that is significantly greater (e.g., 10-20×). As also described further below, while LADA stimulation may be of extremely short duration (e.g., on the order of milliseconds to trigger a soft error through a single upset event), LATS embodiments described herein extend the duration of laser irradiation to hours, days or weeks as a substantial acceleration of aging phenomena that would otherwise require years to accumulate at the ambient temperatures typical of normal use.

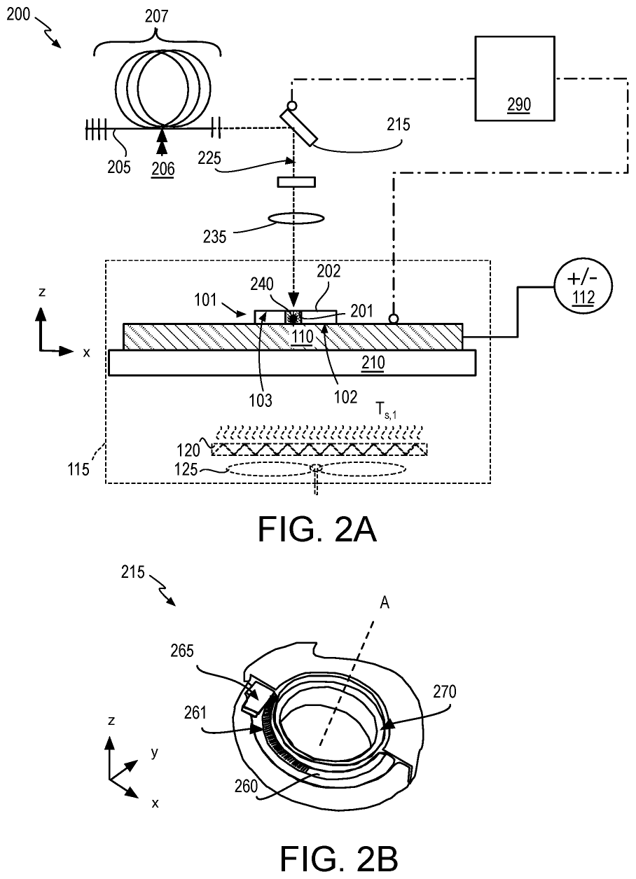

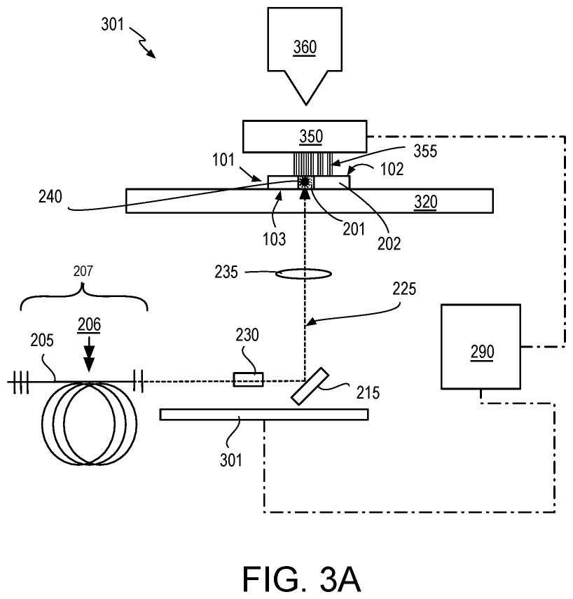

FIG. 2A, FIG. 3A and FIG. 3B illustrate laser-based systems 200, 301 and 302, in accordance with some exemplary embodiments. Each of the laser-based systems 200, 301 and 302 are suitable for practicing spatially selective HTOL methods, for example. Each of the systems 200, 301 and 302 include an electrical test interface operable to exercise one or more functional circuit blocks of an IC device under test (DUT) 101. The electrical test interfaces may place any signal processing and power loads upon any and/or all functional circuitry blocks of DUT 101 including both those targeted for accelerated aging and those that are not. In accordance with some advantageous embodiments, the electrical test interfaces are also operable to measure one or more electrical performance parameters associated with targeted functional circuit blocks of IC DUT 101, either during or following the practice of laser-based spatially selective thermal stressing.

In the exemplary system 200 (FIG. 2A), the electrical test interface includes host applications board 110. For the embodiments illustrated in FIG. 2A, front-side die surface 102 is facing host board 110 with IC DUT 101 having been assembled upon board 110, for example according to any flip-chip assembly technique. In system 200, IC DUT 101 may be a fully packaged die that may be partially deprocessed to expose a bulk substrate on back-side surface 103. Host board 110 may be any board designed to interface with IC DUT 101 under normal operating conditions for any field application. In some examples where IC DUT 101 is a microprocessor including functional IC blocks that execute instructions, host board 110 is a motherboard, for example further comprising a chip set that stores and/or communicates instructions with IC DUT 101. Host board 110 is further coupled to a power supply 112 and is to power IC DUT 101 (e.g., through one or more pair of power rails) in any manner needed to operate IC DUT 101.

Although the electrical test interfaces of systems 200, 301 and 302 may exercise IC DUT 101 with an overvoltage (e.g., 1.5V, or more), in advantageous embodiments the electrical test interfaces are to expose transistors within functional circuit blocks (even those targeted for accelerated aging) to a V_{ds} that is within the normal use threshold rating of the IC device. For example, where IC DUT 101 is a logic or memory device with a normal use V_{ds} rating of 1.2V, the electrical test interfaces of systems 200, 301 and 302 are to exercise target transistors of IC DUT 101 so that a V_{ds} of no more than 1.2V is applied to any transistors within a functional circuit block. Notably, for embodiments where the electric test interface comprises host applications board 110 (e.g., FIG. 2A), power delivery and or thermal power envelop limitations associated applications board 110 pose no difficulty.

In system 301 (FIG. 3A), the electrical test interface includes a microprobe card 350, which further comprises a plurality of microprobes 355 that make electrical contact with any number of testable points (e.g., a top-level of metallization) on a front-side surface 103 of IC DUT 101. In some examples where IC DUT 101 is microprocessor die, front-side die surface 102 may have thousands of testable points having a pitch of 100 μm, or less, which microprobes 355 may contact. For the embodiments illustrated in FIG. 3A, IC DUT 101 is an unpackaged die, or chip with a back side surface 103 supported by a stage 320. One or more of stage 320 and probe card 350 may be displaceable relative to the other. Each of microprobes 355 is an electrically conductive probe pin that extends outwardly from an anchor point on microprobe card 350. Microprobes 355 may be laterally aligned with, and vertically landed upon, test points on front-side surface 102 through the use of any suitable probing microscope 360. Microprobe card 350 electrically couples microprobes 355 to a programmable electrical-testing apparatus (not depicted), which may exercise IC DUT 101 (e.g., during HTOL testing).

In the exemplary system 302 illustrated in FIG. 3B, the electrical test interface includes a tester interface board 310, which may include one or more sockets or other means of electrically interfacing automated test equipment (ATE) 366 with IC DUT 101. For the embodiments illustrated in FIG. 3, front-side IC surface 102 is facing tester interface board 310 with back-side die surface 103 exposed. In system 302, IC DUT 101 may be a singulated die, or chip, that has been at least partially packaged. Alternatively, IC DUT 101 may be in wafer/package panel form suitable for wafer-level/panel-level automated electrical testing.

As illustrated in FIGS. 2A, 3A and 3B, systems 200, 301 and 302 further include a laser source 207 to output a photon beam 225. In exemplary embodiments laser source 207 is a high power, continuous wave (CW) laser. Laser source 207 is advantageously a Class 4 laser, having an average output power of at least 0.5 W. In some exemplary embodiments, laser source 207 has an average output power rating of at least 1 W. Laser source 207 may have an output beam wavelength of 1200 nm-1800 nm. The output wavelength has an energy that is advantageously less than that of the semiconductor bandgap of the channel material of transistors in the functional circuit blocks targeted for irradiation by beam 225.

In exemplary embodiments where an IC DUT comprises silicon-based FETs, laser source 207 has a center output wavelength of 1550 nm. Photon beam 225 at 1550 nm interacts with silicon via the free carriers already present within the conduction band. The energy of photon beam 225 is transferred to the electrons and through collisions to the silicon that results in heat generation. Photon beam 225 is focused (e.g., by objective lens 235) into the substrate semiconductor (e.g., silicon), below or at the device level where transistor structures (e.g., finFETs) are present. In exemplary embodiments, laser beam spot 240 has a radius of 1 um-2 um. Therefore, a large amount of energy can be transferred into a very small volume of DUT 101 resulting in maximum temperatures that can be in excess of 300° C. at spot 240.

The energy of one photon at 1550 nm is 0.8 eV, which is smaller than the silicon bandgap of ˜1 eV. Silicon is therefore generally transparent to a photon beam 225 having a center wavelength of 1550 nm. Beam 225 therefore cannot promote electrons from the valence to the conduction band to itself create electron-hole pairs or free carriers. Notably therefore, beam 225 will not interfere with carrier dynamics (i.e., circuit node currents, circuit node voltages, transistor threshold voltages, etc.) of DUT 101.

In the exemplary systems 200, 301 and 302, laser source 207 is illustrated as a fiber laser 205 with a pump laser 206 that may also be a fiber laser. While such fiber laser architectures are well-known for their high power levels, embodiments herein are not limited to a fiber laser architecture, and laser source 207 may have any architecture capable of achieving the above performance specifications.

As further illustrated, systems 200, 301 and 302 each include a beam steerer, such as one suitable for laser scanning microscopes (LSM), to direct the output of laser source 207 so as to irradiate one or more functional circuit blocks of IC DUT 101. An LSM beam steerer comprises at least a galvanometer 215 and objective lens 235 that are within the path of beam 225. Galvanometer 215 may be any known to be suitable for a scanning microscope, comprising for example a motor, a mirror, and a voltage-feedback based servo driver board that controls galvanometer 215.

In some exemplary embodiments, galvanometer 215 comprises an optical angle encoder that employs a graduated glass disk. FIG. 2B is an isometric illustration of an exemplary optical encoder of galvanometer 215 suitable for the laser-based testing system illustrated in FIG. 2A, in accordance with some embodiments. As shown, the optical angle encoder includes a graduated glass disk 260 upon which there is a grating 261 comprising marks of known pitch and/or line-space duty cycle. With angular rotation about axis A, a scanning unit 265 detects marks of grating 261 as feedback of the angular positional about a coupling bearing 270. The inventors have found such glass-disk galvos provide significantly greater stability than voltage-feedback based servo drivers. As described further below, this greater stability is important for laser-based thermal aging as the duration of laser irradiation during HTOL can extend to several weeks or even months. Even small amounts of positional drift in the photon beam during these extended run times reduces the spatial resolution of the HTOL process and/or introduces error in HTOL models that are predicated on knowing the true duration and temperature stress experienced by a particular functional circuit block. Hence, while servo drivers based on voltage-feedback may be adequate for many LSM applications, servo drivers based on optical feedback are advantageous for HTOL applications described herein to avoid accumulating positional error over the long running times.

As noted above, objective lens 235 is to focus the laser beam to a spot below the surface of IC DUT 101. For example, in system 200 (FIG. 2A) objective lens 235 focuses laser beam 225 through back-side die surface 103 to a focused beam spot 240 having a diameter that is advantageously less than 4 μm, and more advantageously no more than 2 μm. System 301 (FIG. 3A) illustrates an alternative system architecture with bottom-side illumination. For such embodiments, laser beam 225 is focused by objective lens 235 at a point within DUT 101 with beam 225 passing through a transmissive stage material 320, Stage material 320 is advantageously substantially transparent to laser beam 225, with one example being sapphire for examples including a 1550 nm laser source. System 302 illustrates an alternative top-side illumination architecture suitable for ATE where DUTs 101 are coupled to a socket board 310. For system 302, all stage positioning and/or LSM positioning is autonomously performed, and socket board 310 need not be transparent over the band of laser beam 225.

As further illustrated in FIGS. 2A, 3A and 3B, systems 200, 301 and 302 each include a controller 290. Controller 290 is to control the system to irradiate with laser beam 225 only targeted regions of DUT 101. For example, controller 290 executes one or more control loops for steering beam 225 (i.e., LSM control) or positioning stages 210 or 320 relative to beam 225. Controller 290 is responsible for targeting beam 225 to intersect only a targeted portion of DUT 101 (e.g., region 201) while not irradiating any spared DUT portion 202 that is excluded from thermal stress. Controller 290 is further to maintain the beam 225 at the targeted region 201 for a desired duration of beam exposure needed to maintain a predetermined elevated temperature according to a particular HTOL plan. Controller 290 may, for example, maintain beam delivery at one target region 201 for at least 12 hours. Depending on the specific embodiment, controller 290 may maintain beam delivery at one target region 201 for multiple days, multiple weeks, or even a month or more. During this time period, controller 290 executes control loops to actively control parameter drift, such as beam spot position or laser output power. During the time period of targeted irradiation, one or more electrical stresses and/or electrical test parameterizing performance of functional circuitry within target region 201 and/or within spared portion 202 may be performed continuously or periodically. One or more electrical stresses and/or electrical tests parameterizing performance of functional circuitry within target region 201 and/or within spared portion 202 may also be performed following termination of the targeted irradiation.

While spared DUT portion 202 may be maintained at normal operating temperatures while targeted DUT portion 201 is heated by beam 225, selective laser irradiation in accordance with some embodiments may be combined with oven-based temperature stressing to also stress spared DUT portion 202 albeit to a lesser degree than targeted DUT portion 201 which experiences both laser heating and oven heating. For example, DUT portions 202 spared laser irradiation may be heated above room temperature to some reference stress temperature T_{s,1}. Laser irradiation of targeted DUT portion 201 may then provide any higher stress temperature T_{s,2} (e.g., T_{s,1}+ΔT). Hence, any system configured to perform area selective laser-based thermal stressing in accordance with embodiments herein may further include components to elevate the ambient temperature experienced by DUT portion 202 spared laser irradiation. In the embodiment shown in FIG. 2A, for example, oven 115, fan 125 and heater 120 are all illustrated in dashed line to emphasize they are optional components that may be in a system that is to further subject an entirety of DUT 101 to stress temperature T_{s,1} while laser targeted DUT portion 201 is heated by ΔT above that minimum elevated temperature to stress temperature T_{s,2}.

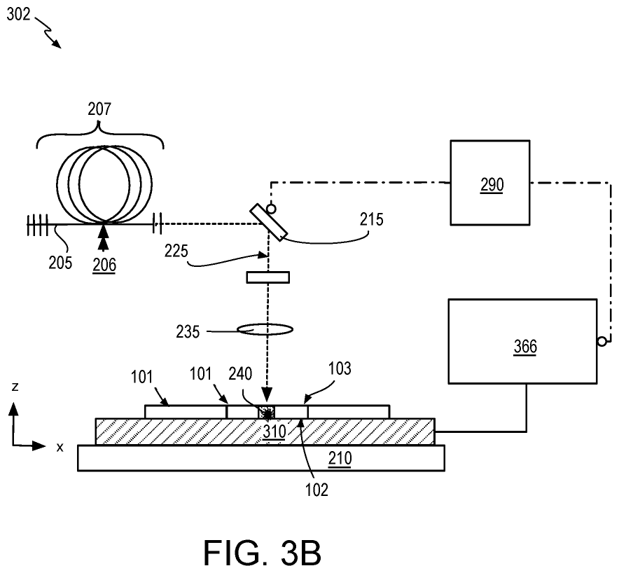

FIG. 4 is a graph illustrating a correlation between laser output power and temperature within a target portion of a DUT, in accordance with some embodiments. In FIG. 4, laser output optical power is provided on the x-axis with the measured temperature of a silicon thermal diode within a targeted region of a DUT plotted to the y-axis. This example illustrates the measurements to follow a linear power-temperature relationship. FIG. 4 further illustrates the high temperatures achievable with laser irradiation (e.g., 300° C.), which can reduce HTOL stress times (e.g., from weeks to days).

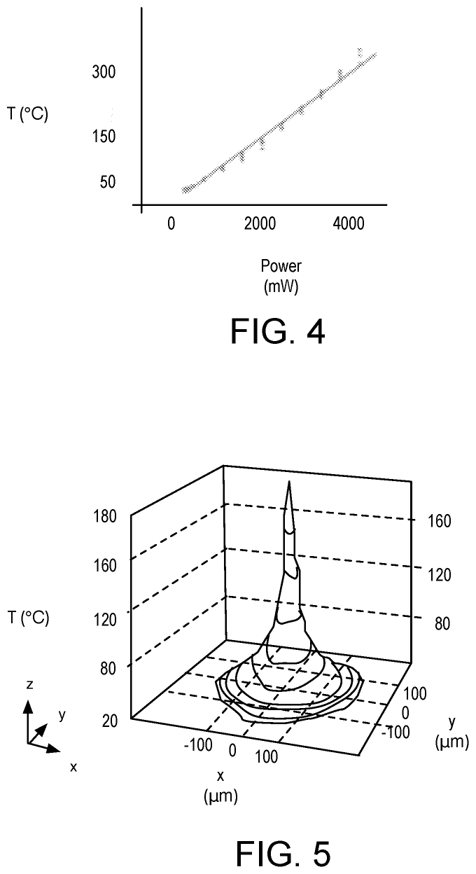

FIG. 5 is a graph illustrating a spatial temperature profile spanning a target portion of a DUT heated in accordance with some embodiments. The illustrated thermal spatial profile was characterized experimentally by moving the laser spot around a thermal diode. As shown, the targeted DUT portion experiencing elevated temperatures resulting from laser irradiation at a spot centered at 0,0 in the x-y plane spans a DUT area that is roughly circular and has a radius of ˜300 μm. In this example, a peak temperature of 180° C. is achieved with a temperature of greater than 120° C. over a radius of ˜40 um. Temperature declines from the maximum temperature with increasing distance from the point of maximum temperature at a rate of at least 80° C./100 um. In the illustrated example, temperature drops to ˜70 C at a radius of 200 um. The spatial distribution of hot-spot temperature within a target DUT region can therefore be highly localized and will vary as a function of material (e.g., silicon) thickness and the laser power.

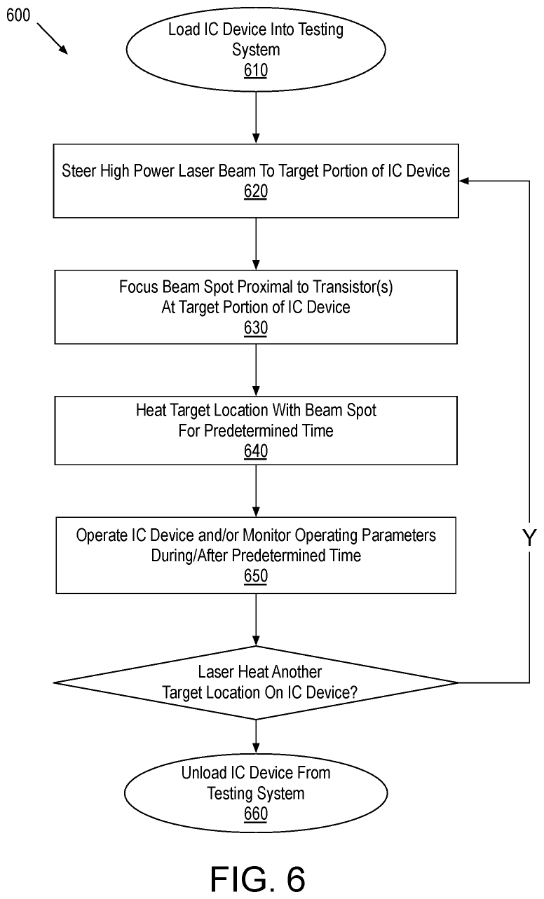

FIG. 6 is a flow diagram illustrating laser-based methods 600 for inducing localized hot spots at the circuit level within an IC DUT that is otherwise under nominal conditions, in accordance with some embodiments. Methods 600 may be practiced with any of the laser-based probing systems 201, 301, or 302, for example. To execute methods 600, controller 290 (FIG. 2A) may be programmed with instructions stored on a computer readable media, such as a magnetic hard drive, a RAM, or the like.

Methods 600 begin at input 610 where an IC device is loaded into a testing system, such as any of systems 200, 301 or 302. At block 620, a high-power (e.g., Class 4) laser is energized and the photon beam steered to a targeted portion of the IC DUT where one or more functional circuit blocks (e.g., comprising many FET structures) are located. Beam steering at block 620 may comprise one or more of galvo control or control of a linear stage, such as laser stage 320 (FIG. 3A). At block 630, the beam spot is focused within a field of view of the LSM and at a depth within IC DUT proximal to a device layer (e.g., near channel regions of transistor structures).

Methods 600 continue at block 640 where the laser power, beam direction, and spot focal depth are actively controlled in a hold condition to irradiate a targeted portion of the IC DUT generating heat in the localized area for a predetermined time. At block 650, the IC DUT is operated through an electrical tester interface either during the execution of block 640, or after the predetermined duration of block 640 has completed. For embodiments where block 650 is executed concurrently with block 640, continuous or periodic electrical stimulus and/or testing may be performed. In some advantageous embodiments, the electrical stimulus is limited to “normal use” conditions. In other embodiments, electrical stimulus may be more extreme than normal use conditions, for example through the application of an overvoltage to power supply rails. Electrical stimulus and the corresponding test parameter data collected at block 650 may pertain to any accelerated lifetime testing protocol or be directed at experimental validation of thermal simulation. Some specific examples include fin self-heat (FISH) testing, negative bias temperature instability (NBTI) testing, time-dependent dielectric breakdown (TDDB) testing, or highly accelerated electromigration lifetime testing (HALT).

In some embodiments blocks 640 and 650 may be executed for as little as a half a day to a couple days because the laser-induced temperature stress within localized target portions of a DUT can be very high (e.g., greater than 300° C.). However, in some embodiments blocks 640 and 650 may also be executed for a month, or more. The data collected at block 650 is highly focused on circuitry within the small targeted portion of the DUT, as opposed to an entire die. The spatial resolution of the collect date improves the odds of rapidly identifying a failure and determining a root cause. Interpretation of the data collected at block 650 is also easier to as any side effects of the acceleration are limited to the targeted portion of the DUT.

Methods 600 may continue with a repositioning of the laser beam spot to another target location of the same DUT with blocks 620-650 then repeated to thermally stress the new target region. Such partitioning of temperature stress effects is not possible where an entire DUT is stressed concurrently. Any number of functional circuit blocks within a DUT may be iteratively stressed thermally with a laser-based probe system according to methods 600. For example, a round-robin application of temperature stress to a plurality of functional circuit blocks may implement a controlled thermal effects characterization comprising validation of temperature design limits and/or temperature aging/sensitivity analysis. After all desired functional IC blocks have been heated with laser assist, methods 600 then complete at output 660 where the IC DUT is unloaded from the testing system.

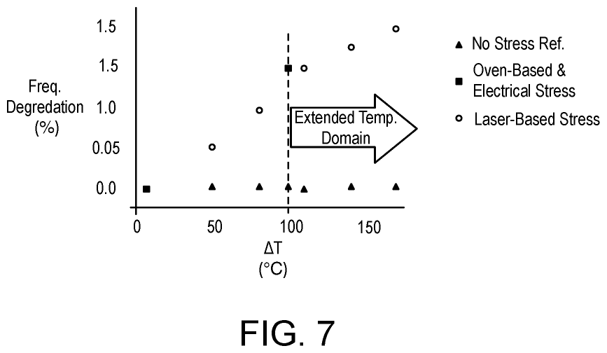

FIG. 7 is a graph illustrating temperature sensitivity of a PLL circuit as temperature is increased from 22 C to 170° C., in accordance with some embodiments. Square markers in FIG. 7 depict a frequency degradation measured for a phase-locked loop circuit of a first DUT. The PLL circuit was first tested at room temperature and then subjected to a conventional oven-based thermal stress at 100° C. For this treatment, an electrical stress was applied in a manner typical for oven-based HTOL studies. Circular markers in FIG. 7 depict a frequency degradation measured for the same PLL circuit of a second DUT. This PLL was tested while laser heating to 50° C., 80° C., 110° C., 140° C., and 170° C. A number of these laser-induced hot spot temperatures fall within an extended temperature domain, which is not readily achieved with an oven-based system. However, at temperatures below the extended temperature domain, there is agreement between the electrical and laser stresses. Triangular markers in FIG. 7 illustrate a second PLL of the second DUT that is outside of the targeted DUT region irradiated by the laser. As shown, there is substantially no frequency degradation for this second (witness) PLL, which illustrates the selectivity possible with laser-based thermal stressing in accordance with embodiments. Accordingly, embodiments herein enable a selective stress of functional circuit block while the remaining parts of the DUT are not similarly stressed and therefore do not contribute to the failure rate.

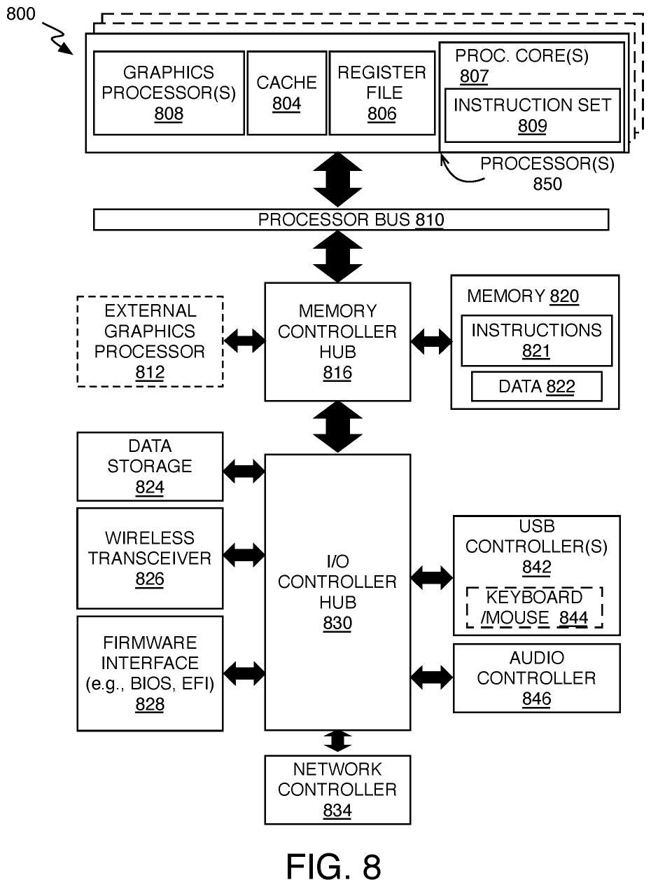

FIG. 8 is a block diagram of a data processing system 800 that may be utilized to perform laser-assisted temperature stressing of an IC device under test. Data processing system 800 includes one or more processors 850 and one or more graphics processors 808, and may be implemented in a single processor desktop system, a multiprocessor workstation system, or a server system having a large number of processors 850 or processor cores 807.

In some embodiments, the one or more processors 850 each include one or more processor cores 807 to process instructions which, when executed, perform operations for system and user software. In some embodiments, each of the one or more processor cores 807 is configured to process a specific instruction set 809. In some embodiments, instruction set 809 may facilitate Complex Instruction Set Computing (CISC), Reduced Instruction Set Computing (RISC), or computing via a Very Long Instruction Word (VLIW). Multiple processor cores 807 may each process a different instruction set 809, which may include instructions to facilitate the emulation of other instruction sets. Processor cores 807 may also include other processing devices, such a Digital Signal Processor (DSP).

In some embodiments, processor 850 includes cache memory 804. Depending on the architecture, processor 850 can have a single internal cache or multiple levels of internal cache. In some embodiments, the cache memory is shared among various components of processors 850. In some embodiments, processors 850 also use an external cache (e.g., a Level-3 (L3) cache or Last Level Cache (LLC)) (not shown), which may be shared among processor cores 807, for example. A register file 806 is additionally included in processor 850 which may include different types of registers for storing different types of data (e.g., integer registers, floating point registers, status registers, and an instruction pointer register). Some registers may be general-purpose registers, while other registers may be specific to the design of the processor 850.

In some embodiments, processors 850 are coupled to a processor bus 810 to transmit data signals between processors 850 and other components in system 800. System 800 has a ‘hub’ system architecture, including a memory controller hub 816 and an input output (I/O) controller hub 830. Memory controller hub 816 facilitates communication between a memory device and other components of system 800, while I/O Controller Hub (ICH) 830 provides connections to I/O devices via a local I/O bus.

Memory device 820 can be a dynamic random access memory (DRAM) device, a static random access memory (SRAM) device, flash memory device, or some other memory device having suitable performance to serve as process memory. Memory 820 can store data 822 and instructions 821 for use when processor 802 executes a process. Memory controller hub 816 also couples with an optional external graphics processor 812, which may communicate with the one or more graphics processors 808 and/or processors 850 to perform various operations.

In some embodiments, ICH 830 enables peripherals to connect to memory 820 and processor 802 via a high-speed I/O bus. The I/O peripherals include an audio controller 846, a firmware interface 828, a wireless transceiver 826 (e.g., Wi-Fi, Bluetooth), and a data storage device 824 (e.g., hard disk drive, flash memory, etc.). One or more Universal Serial Bus (USB) controllers 842 may connect input devices, such as keyboard and mouse 844 combinations. A network controller 834 may also couple to ICH 830. In some embodiments, a high-performance network controller (not shown) couples to processor bus 810.

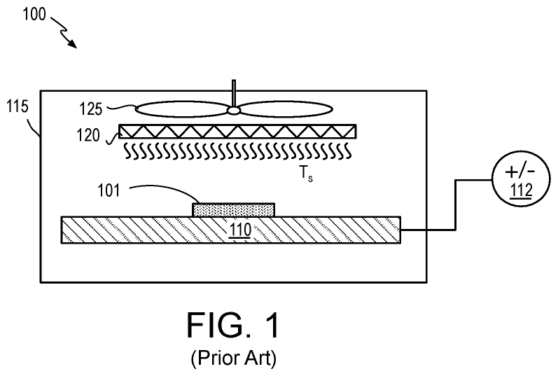

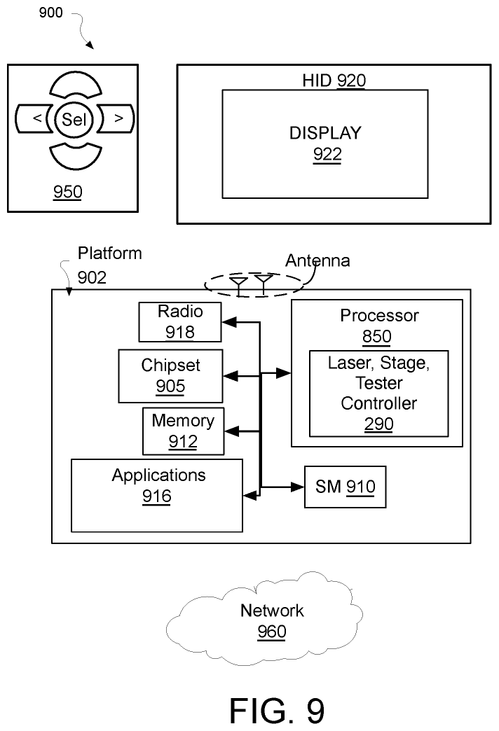

FIG. 9 is a diagram of an exemplary system 900, in accordance with one or more embodiments. System 900 may be a desktop or laptop computer although system 900 is not limited to this context. System 900 includes a device platform 902 that may implement all or a subset of the laser-assisted temperature stressing methods described above in the context of FIG. 1-7. In various exemplary embodiments, processors 850 executes laser control methods and test system control methods, for example as described elsewhere herein. In the illustrated embodiment, processor 850 includes logic circuitry implementing controller 290, for example as described elsewhere herein. In some embodiments, one or more computer readable media may store instructions, which when executed by a processor 850, cause the processor(s) to execute one or more of the laser, stage, scanning microscope, and/or electrical tester operations, for example as described elsewhere herein.

In embodiments, device platform 902 is coupled to a human interface device (HID) 920. Platform 902 may collect tester data with scanning microscope module 910, which is processed and output to HID 920. A navigation controller 950 including one or more navigation features may be used to interact with, for example, device platform 902 and/or HID 920. In embodiments, HID 920 may include any monitor or display 922 coupled to platform 902 via radio 918 and/or network 960. HID 920 may include, for example, a computer display screen, touch screen display, video monitor, television-like device, and/or a television.

In embodiments, device platform 902 may include any combination of scanning microscope module 910, chipset 905, processors 850, memory/storage 912, applications 916, and/or radio 918. Chipset 905 may provide intercommunication among processors 850, memory 912, applications 916, or radio 918.

Memory 912 may be implemented as a volatile memory device such as, but not limited to, a Random Access Memory (RAM), Dynamic Random Access Memory (DRAM), or Static RAM (SRAM). Memory 912 may also be implemented as a non-volatile storage device such as, but not limited to flash memory, battery backed-up SDRAM (synchronous DRAM), magnetic memory, phase change memory, and the like.

In embodiments, system 900 may be implemented as a wireless system, a wired system, or a combination of both. When implemented as a wireless system, system 900 may include components and interfaces suitable for communicating over a wireless shared media, such as one or more antennas, transmitters, receivers, transceivers, amplifiers, filters, control logic, and so forth. An example of wireless shared media may include portions of a wireless spectrum, such as the RF spectrum and so forth. When implemented as a wired system, system 900 may include components and interfaces suitable for communicating over wired communications media, such as input/output (I/O) adapters, physical connectors to connect the I/O adapter with a corresponding wired communications medium, a network interface card (NIC), disc controller, video controller, audio controller, and the like. Examples of wired communications media may include a wire, cable, metal leads, printed circuit board (PCB), backplane, switch fabric, semiconductor material, twisted-pair wire, co-axial cable, fiber optics, and so forth.

As exemplified above, embodiments described herein may be implemented using hardware elements, software elements, or a combination of both. Examples of hardware elements or modules include: processors, microprocessors, circuitry, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. Examples of software elements or modules include: applications, computer programs, application programs, system programs, machine programs, operating system software, middleware, firmware, routines, subroutines, functions, methods, procedures, software interfaces, application programming interfaces (API), instruction sets, computing code, computer code, code segments, computer code segments, data words, values, symbols, or any combination thereof. Determining whether an embodiment is implemented using hardware elements and/or software elements may vary in accordance with any number of factors considered for the choice of design, such as, but not limited to: desired computational rate, power levels, heat tolerances, processing cycle budget, input data rates, output data rates, memory resources, data bus speeds and other design or performance constraints.

One or more aspects of at least one embodiment may be implemented by representative instructions stored on a machine-readable storage medium. Such instructions may reside, completely or at least partially, within a main memory and/or within a processor during execution thereof by the machine, the main memory and the processor portions storing the instructions then also constituting a machine-readable storage media. Programmable logic circuitry may have registers, state machines, etc. configured by the processor implementing the computer readable media. Such logic circuitry, as programmed, may then be understood as physically transformed into a system falling within the scope of at least some embodiments described herein. Instructions representing various logic within the processor, which when read by a machine may also cause the machine to probe IC devices under test to perform the techniques described herein. Such representations may be stored on a tangible, machine-readable medium and supplied to various customers or manufacturing facilities to load into the electrical testing machines that analyze the circuitry of an IC device under test.

It will be recognized that embodiments are not limited to the examples described in detail above, but can be practiced with modification and alteration without departing from the scope of the appended claims. For example, the above embodiments may include specific combinations of features as further provided below.

In first examples, an integrated circuit (IC) device testing apparatus comprises a stage comprising an area to support an IC device under test (DUT). The apparatus comprises a laser source to output a beam of photons, a controller to heat with the beam a target portion of the DUT for a predetermined time, and an electrical test interface to operate the DUT during, or after, the predetermined time.

In second examples, for any of the first examples the laser source has an average output power rating of at least 1 W.

In third examples, for any of the first through third examples the DUT is to comprise a semiconductor material having a bandgap, and the laser source has an output energy less than the bandgap.

In fourth examples, for any of the first through third examples the laser source has continuous wave output with a center wavelength of 1200 nm-1800 nm.

In fifth examples, for any of the fourth examples the output center wavelength is 1550 nm.

In sixth examples, for any of the first through fifth examples the IC device testing apparatus further comprises a beam steering system coupled to the controller, the beam steering system to focus a spot of the beam within the target portion of the DUT.

In seventh examples, for any of the sixth examples the spot of the beam has a diameter no more than 2 μm.

In eighth examples, for any of the first through seventh examples the beam steering system comprises a galvanometer further comprising an optical encoder.

In ninth examples, for any of the first through eighth examples the target portion is to reach a maximum temperature that is at least 150° C. greater than a second portion of the DUT not irradiated by the beam.

In tenth examples, for any of the ninth examples the temperature of the DUT is to decline from the maximum temperature with increasing distance from a point of maximum temperature at a rate of at least 80° C./100 μm.

In eleventh examples, for any of the first through tenth examples the predetermined time is at least 12 hours.

In twelfth examples, for any of the first through eleventh examples the electrical test interface comprises a microprobe card comprising a microprobe array, a host applications board coupled to a power supply to power the IC device, or a probe card electrically coupled to automated test equipment (ATE).

In thirteenth examples, for any of the first through twelfth examples the stage comprises a material transparent to the laser beam and the beam is to pass through the stage.

In fourteenth examples, a method of testing an integrated circuit (IC) device comprises selectively heating a target portion of an IC device under test (DUT) by exposing the target portion to a laser beam for a predetermined time, and operating the DUT during, or after, the predetermined time.

In fifteenth examples, for any of the fourteenth examples the DUT comprises a substrate material and exposing the target portion to the laser beam further comprises passing the beam through a thickness of the substrate.

In sixteenth examples, for any of the fourteenth through fifteenth examples selectively heating the target portion of the DUT further comprises generating the laser beam with a continuous wave laser source having an output power rating of at least 1 W at an output center wavelength of 1200 nm-1800 nm.

In seventeenth examples, for any of the fourteenth through sixteenth examples exposing the target portion to the laser beam further comprises steering the beam with a galvanometer comprising an optical encoder.

In eighteenth examples, for any of the fourteenth through seventeenth examples the predetermined time exceeds 12 hours and operating the DUT further comprises supplying a normal-use voltage to the DUT for the predetermined time concurrent with exposing the target portion to the laser beam.

In nineteenth examples, for any of the fourteenth through eighteenth examples the method further comprises globally heating the entire DUT with a second heat source while concurrently selectively heating the target portion of the DUT with the laser beam.

In twentieth examples, a method of testing an integrated circuit (IC) device comprises receiving an IC device comprising a plurality of substantially identical functional circuit blocks, selectively heating a first of the plurality of functional circuit blocks without heating a second of the functional circuit blocks by exposing the first of the functional circuit blocks to a laser beam for a predetermined time, and determining an amount of degradation between the first and second functional circuit blocks by operating the plurality of functional circuit blocks during, or after, the predetermined time.

In twenty-first examples, for any of the twentieth examples the IC device comprises a processor including circuitry to execute an instruction set, and the functional circuit blocks comprise at least one of a ring oscillator, a phase locked loop, or a memory array.

In twenty-second examples, for any of the twentieth through twenty-first examples exposing the first of the functional circuit blocks to the laser beam for a predetermined time further comprises exposing the first of the functional circuit blocks to a laser beam with a power rating of at least 1 W and an output center wavelength of 1200 nm-1800 nm for at least 12 hours.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

What is claimed is:

1. An integrated circuit (IC) device testing apparatus, comprising:
a stage comprising an area to support an IC device under test (DUT);
a laser source to output a beam of photons;
a controller to heat with the beam a target portion of the DUT for a predetermined time; and
an electrical test interface to operate the DUT during, or after, the predetermined time.

2. The IC device testing apparatus of claim 1, wherein the laser source has an average output power rating of at least 1 W.

3. The IC device testing apparatus of claim 2, wherein:
the DUT is to comprise a semiconductor material having a bandgap; and
the laser source has an output energy less than the bandgap.

4. The IC device testing apparatus of claim 2, wherein the laser source has continuous wave output with a center wavelength of 1200 nm-1800 nm.

5. The IC device testing apparatus of claim 4, wherein the output center wavelength is 1550 nm.

6. The IC device testing apparatus of claim 1, further comprising a beam steering system coupled to the controller, the beam steering system to focus a spot of the beam within the target portion of the DUT.

7. The IC device testing apparatus of claim 6, wherein the spot of the beam has a diameter no more than 2 μm.

8. The IC device testing apparatus of claim 6, wherein the beam steering system comprises a galvanometer further comprising an optical encoder.

9. The IC device testing apparatus of claim 1, wherein the target portion is to reach a maximum temperature that is at least 150° C. greater than a second portion of the DUT not irradiated by the beam.

10. The IC device testing apparatus of claim 9, wherein the temperature of the DUT is to decline from the maximum temperature with increasing distance from a point of maximum temperature at a rate of at least 80° C./100 μm.

11. The IC device testing apparatus of claim 1, wherein the predetermined time is at least 12 hours.

12. The IC device testing apparatus of claim 1, wherein the electrical test interface comprises:
a microprobe card comprising a microprobe array;
a host applications board coupled to a power supply to power the IC device; or
a probe card electrically coupled to automated test equipment (ATE).

13. The IC device testing apparatus of claim 1, wherein the stage comprises a material transparent to the laser beam and the beam is to pass through the stage.

14. A method of testing an integrated circuit (IC) device, the method comprising:
selectively heating a target portion of an IC device under test (DUT) by exposing the target portion to a laser beam for a predetermined time; and
operating the DUT during, or after, the predetermined time.

15. The method of claim 14, wherein the DUT comprises a substrate material and exposing the target portion to the laser beam further comprises passing the beam through a thickness of the substrate.

16. The method of claim 14, wherein selectively heating the target portion of the DUT further comprises generating the laser beam with a continuous wave laser source having an output power rating of at least 1 W at an output center wavelength of 1200 nm-1800 nm.

17. The method of claim 14, wherein exposing the target portion to the laser beam further comprises steering the beam with a galvanometer comprising an optical encoder.

18. The method of claim 14, wherein the predetermined time exceeds 12 hours and wherein operating the DUT further comprises supplying a normal-use voltage to the DUT for the predetermined time concurrent with exposing the target portion to the laser beam.

19. The method of claim 14, further comprises globally heating the entire DUT with a second heat source while concurrently selectively heating the target portion of the DUT with the laser beam.

20. A method of testing an integrated circuit (IC) device, the method comprising:
receiving an IC device comprising a plurality of substantially identical functional circuit blocks;
selectively heating a first of the plurality of functional circuit blocks without heating a second of the functional circuit blocks by exposing the first of the functional circuit blocks to a laser beam for a predetermined time; and
determining an amount of degradation between the first and second functional circuit blocks by operating the plurality of functional circuit blocks during, or after, the predetermined time.

21. The method of claim 20, wherein the IC device comprises a processor including circuitry to execute an instruction set, and wherein the functional circuit blocks comprise at least one of a ring oscillator, a phase locked loop, or a memory array.

22. The method of claim 20, wherein exposing the first of the functional circuit blocks to the laser beam for a predetermined time further comprises exposing the first of the functional circuit blocks to a laser beam with a power rating of at least 1 W and an output center wavelength of 1200 nm-1800 nm for at least 12 hours.
